(19) United States
(12) Patent Application Publication
(10) Pub. No.: US 2019/0044306 A1
(43) Pub. Date: Feb. 7, 2019

(54) VERTICAL CAVITY SURFACE EMITTING LASER, METHOD FOR FABRICATING VERTICAL CAVITY SURFACE EMITTING LASER

(71) Applicant: SUMITOMO ELECTRIC INDUSTRIES, LTD., Osaka (JP)

(72) Inventors: Toshiyuki TANAHASHI, Osaka (JP); Takashi ISHIZUKA, Osaka (JP); Susumu YOSHIMOTO, Osaka (JP); Takamichi SUMITOMO, Osaka (JP); Koji NISHIZUKA, Osaka (JP); Kei FUJI, Osaka (JP); Suguru ARIKATA, Osaka (JP)

(73) Assignee: SUMITOMO ELECTRIC INDUSTRIES, LTD., Osaka (JP)

(21) Appl. No.: 16/049,496

(22) Filed: Jul. 30, 2018

(30) Foreign Application Priority Data
Aug. 7, 2017 (JP) 2017-152606

(51) Int. Cl. H01S 5/187; H01S 5/042; H01S 5/343; H01S 5/30; H01S 5/028; H01S 5/183

(52) U.S. Cl. CPC H01S 5/187; H01S 5/0421; H01S 5/34313; H01S 5/3086; H01S 2304/04; H01S 5/18313; H01S 5/0425; H01S 2304/02; H01S 5/028

(57) ABSTRACT

A vertical cavity surface emitting laser includes: an active layer; a first laminate for a first distributed Bragg reflector; and a first intermediate layer disposed between the active layer and the first laminate. The first intermediate layer has first and second portions. The first laminate, the first and second portions of the first intermediate layer, and the active layer are arranged along a direction of a first axis. The first laminate and the first portion of the first intermediate layer each include a first dopant. The active layer has a first-dopant concentration of less than 1×10¹⁶ cm⁻³. The first portion of the first intermediate layer has a first-dopant concentration smaller than that of the first laminate. The second portion of the first intermediate layer has a first-dopant concentration smaller than that of the first portion of the first intermediate layer.

### BACKGROUND OF THE INVENTION

### Field of the Invention

The present invention relates to a vertical cavity surface emitting laser and a method for fabricating a vertical cavity surface emitting laser. This application claims the benefit of priority from Japanese Patent Application No. 2017-152606 filed on Aug. 7, 2017, which is herein incorporated by reference in its entirety.

### Related Background Art

Japanese Patent Application Laid-Open No. 2007-142375 discloses a vertical cavity surface emitting laser.

### SUMMARY OF THE INVENTION

A vertical cavity surface emitting laser according to one aspect includes: an active layer; a first laminate for a first distributed Bragg reflector; and a first intermediate layer disposed between the active layer and the first laminate. The first intermediate layer has a first portion and a second portion. The first laminate, the first portion and the second portion of the first intermediate layer, and the active layer are arranged along a direction of a first axis. The first laminate and the first portion of the first intermediate layer each include a first dopant. The active layer has a concentration of the first dopant of less than 1×10¹⁶ cm⁻³. The first portion of the first intermediate layer extends from the first laminate to the second portion of the first intermediate layer, and the second portion of the first intermediate layer extends from the first portion of the first intermediate layer to the active layer. The first portion of the first intermediate layer has a concentration of the first dopant smaller than that of the first laminate, and the second portion of the first intermediate layer has a concentration smaller than that of the first portion of the first intermediate layer.

A method for making a vertical cavity surface emitting laser according another aspect includes: growing a semiconductor region on a substrate; and heating the semiconductor region and the substrate at a heating temperature. The semiconductor region includes a first laminate for a first distributed Bragg reflector, a second laminate for a second distributed Bragg reflector, a first semiconductor film for a first intermediate region, and a third semiconductor laminate for an active layer. The first laminate, the first semiconductor film, the third semiconductor laminate, and the second laminate are arranged on a principal surface of the substrate. Growing a semiconductor region on a substrate includes growing the first laminate with a first dopant, and growing the first intermediate region without the first dopant.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a partially cutaway schematic view showing a vertical cavity surface emitting laser according to the present embodiment.

FIG. 2 is a schematic view showing a major step in a method for fabricating the vertical cavity surface emitting laser according to the embodiment.

FIG. 3 is a schematic view showing a major step in the method according to the embodiment.

FIG. 4 is a schematic view showing a major step in the method according to the embodiment.

FIG. 5 is a schematic view showing a major step in the method according to the embodiment.

FIG. 6 is a schematic view showing a major step in the method according to the embodiment.

FIG. 7 is a schematic view showing a major step in the method according to the embodiment.

FIG. 8 is a view showing three profiles of n-type dopant of vertical cavity surface emitting lasers over the first laminate, the intermediate region and the active layer.

### DESCRIPTION OF THE EMBODIMENTS

Application fields, such as optical communications, using a vertical cavity surface emitting laser require high-speed modulation and low threshold. The inventors' findings reveal that the high-speed modulation and the low threshold can be brought to the vertical cavity surface emitting laser by reducing the diameter of the current aperture and/or using an active layer of a strained quantum well structure. Further improvement in modulation speed needs another approach, which is different from the strained quantum well structure and the reduction in the current aperture diameter.

It is an object of one aspect of the present invention to provide a vertical cavity surface emitting laser having a semiconductor region, enabling a high-rate modulation, between the active layer and a laminate for distributed Bragg reflection. It is an object of another aspect of the present invention to provide a method of fabricating a vertical cavity surface emitting laser having a semiconductor region, enabling a high-rate modulation, between the active layer and the laminate.

A description will be given of the present above aspects below.

A vertical cavity surface emitting laser according to an embodiment includes: (a) an active layer; (b) a first laminate for a first distributed Bragg reflector; and (c) a first intermediate layer disposed between the active layer and the first laminate. The first intermediate layer has a first portion and a second portion. The first laminate, the first portion and the second portion of the first intermediate layer, and the active layer are arranged along a direction of a first axis. The first laminate and the first portion of the first intermediate layer each include a first dopant. The active layer has a concentration of the first dopant of less than 1×10¹⁶ cm⁻³. The first portion of the first intermediate layer extends from the first laminate to the second portion of the first intermediate layer, and the second portion of the first intermediate layer extends from the first portion of the first intermediate layer to the active layer. The first portion of the first intermediate layer has a concentration of the first dopant smaller than that of the first laminate, and the second portion of the first intermediate layer has a concentration smaller than that of the first portion of the first intermediate layer.

The vertical cavity surface emitting laser provides the first intermediate region, which is disposed between the active layer and the first laminate, with the first and second portions. In the first intermediate region, the first portion extends from the first laminate to the second portion, and the second portion extends from the active layer to the first portion. In the first intermediate region, the second portion has a first-dopant concentration lower than that of the first portion, so that the active layer is provided with the first-dopant concentration less than 1×10¹⁶ cm⁻³. The first intermediate region that is provided with the second portion between the active layer and the first portion brings the vertical cavity surface emitting laser a structure which can hinder the dopant atoms in the first laminate from reaching the active layer in the fabrication thereof by diffusion, so that the active layer is provided with a very low dopant concentration, for example, smaller than a lower detection limit. The second portion of the lower dopant concentration makes the density of non-radiative recombination centers in the active layer very low. The first portion having a higher dopant concentration (which is more than that of the second portion of the first intermediate region and less than that of the first laminate) is disposed on the carrier-flowing path from the first laminate to the active layer.

In the vertical cavity surface emitting laser according to an embodiment, the first laminate includes a lower contact layer; the first dopant includes at least one of silicon, sulfur, or tellurium; the first laminate has a concentration of an n-type dopant of 1×10¹⁸ cm⁻³ or more; and the active layer is separated from the first laminate by a distance of 5 nm or more.

The vertical cavity surface emitting laser allows the first intermediate region to separate the first laminate, which has a high n-type dopant concentration of 1×10¹⁸ cm⁻³ or more, from the active layer. In the fabrication of the vertical cavity surface emitting laser, semiconductor layers for the first laminate are gown, and the remaining semiconductor layers are grown on these semiconductor layers for the first laminate, so that the semiconductor layers for the first laminate is subjected to a heating process in growing the remaining semiconductor layers. The total amount of thermal energy applied to the semiconductor layers for the first laminate is associated with not the thickness of the first laminate but the total thickness of the remaining semiconductor layers. The first intermediate region, which is disposed between the first laminate and the active layer, is provided with the first and second portions having dopant concentrations different from each other, which are formed by n-type dopant diffusion from the first laminate of 1×10¹⁸ cm⁻³ or more during the fabrication, thereby making the dopant concentration in the active layer very low, for example, smaller than a lower detection limit.

In the vertical cavity surface emitting laser according to an embodiment, the first portion of the first intermediate layer has a concentration of the first dopant of 1×10¹⁷ cm⁻³ or more, and the second portion of the first intermediate layer has a concentration of the first dopant of less than 1×10¹⁷ cm⁻³.

The vertical cavity surface emitting laser can provide the first portion having a first-dopant concentration of 1×10¹⁷ cm⁻³ or more and the second portion having a first-dopant concentration of less than 1×10¹⁷ cm⁻³ with a dopant profile monotonically changing in the direction from the first laminate to the active layer.

In the vertical cavity surface emitting laser according to an embodiment, the active layer has a quantum well structure of Al_{X}Ga_{1-X}As/In_{1-Y}Ga_{Y}As, where X is not less than 0.1 and not more than 0.5, and Y is not less than 0.05 and not more than 0.5, i.e., 0.1≤X≤0.5, and 0.05≤Y≤0.5.

The vertical cavity surface emitting laser can provide the above quantum well structure with a reduction in the generation of non-radiative recombination centers, which is produced by the dopant diffusion.

In the vertical cavity surface emitting laser according to an embodiment, the active layer has a quantum well structure of In_{U}Al_{V}Ga_{1-U-V}As/Al_{X}Ga_{1-X}As, where U is not less than 0.05 and not more than 0.5, V is more than zero and not more than 0.2, and X is not less than 0.1 and not more than 0.5, i.e., 0.05≤U≤0.5, 0<V≤0.2, and 0.1≤X≤0.5.

The vertical cavity surface emitting laser can provide the above quantum well structure with a reduction in the generation of the non-radiative recombination center, which is caused by the dopant diffusion.

The vertical cavity surface emitting laser according to an embodiment further includes: a substrate; a second laminate for a second distributed Bragg reflector; and a second intermediate region disposed between the active layer and the second laminate. The second intermediate layer has a first portion and a second portion. The first intermediate layer and the first laminate are disposed between the substrate and the active layer. The active layer is disposed between the first and second laminates. The second laminate, the first and second portions of the second intermediate region, and the active layer are arranged along the direction of the first axis.

The vertical cavity surface emitting laser is provided with a structure having the first intermediate region and the first laminate between the substrate and the active layer, and this structure results in that the first intermediate region and the first laminate are subjected to a high temperature process during the growth of the upper region including the second intermediate region and the second laminate in the film formation for the vertical cavity surface emitting laser.

A method for making a vertical cavity surface emitting laser according an embodiment includes: (a) growing a semiconductor region on a substrate; and (b) heating the semiconductor region and the substrate at a heating temperature. The semiconductor region includes a first laminate for a first distributed Bragg reflector, a second laminate for a second distributed Bragg reflector, a first semiconductor film for a first intermediate region, and a third semiconductor laminate for the active layer. The first laminate, the first semiconductor film, the third semiconductor laminate, and the second laminate are arranged on a principal surface of the substrate. Growing a semiconductor region on a substrate includes growing the first laminate with a first dopant, and growing the first intermediate region without the first dopant.

The method of making a vertical cavity surface emitting laser applies an additional heat treatment, which is different from the heating resulting from the semiconductor growth, to all the semiconductor layers for the vertical cavity surface emitting laser as grown to form a desired profile by diffusion. Specifically, raw material gas is supplied to a growth reactor to grow semiconductor laminates on the substrate, thereby obtaining a semiconductor product. The semiconductor product is subjected to an additional heat treatment without growing any semiconductor. This heat treatment allows the first dopant atoms to diffuse independently of the heating for the growth. The thermal treatment makes it possible to form a dopant profile monotonically varying in a semiconductor layer, which is grown as undoped, for the first intermediate region in the direction from the first distributed Bragg reflector to the first intermediate region.

In the method according to an embodiment, the heating temperature is 700 degrees Celsius or more.

This method according to an embodiment uses a heat treatment temperature of 700 degrees Celsius or higher for the heat treatment.

In the method according to an embodiment, heating the semiconductor region and the substrate is conducted for an hour or more.

The method uses the heat treatment time of 1 hour or more.

Teachings of the present invention can be readily understood by considering the following detailed description with reference to the accompanying drawings shown as examples. Referring to the accompanying drawings, embodiments of a vertical cavity surface emitting laser, and a method for fabricating a vertical cavity surface emitting laser according to the present invention will be described below. To facilitate understanding, identical reference numerals are used, where possible, to designate identical elements that are common to the figures.

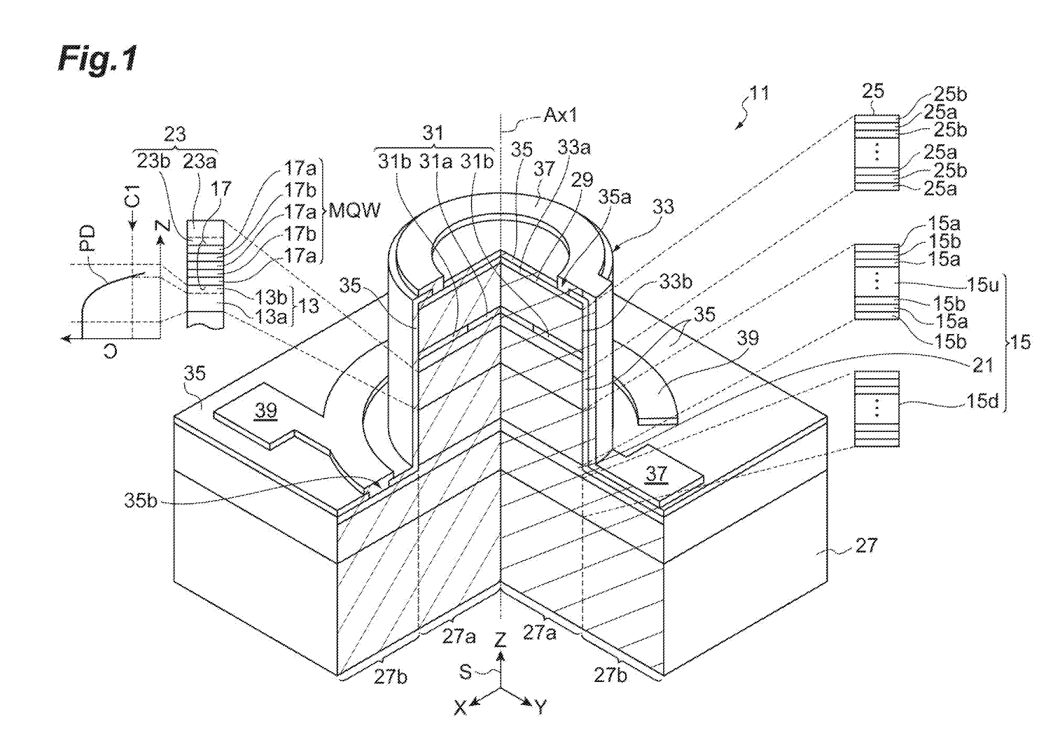

FIG. 1 is a partially cutaway schematic view showing a vertical cavity surface emitting laser according to the present embodiment. In FIG. 1, an orthogonal coordinate system S is depicted, and the Z-axis is oriented in the direction of the first axis Ax1. The vertical cavity surface emitting laser 11 includes a first intermediate layer 13, a first laminate 15, and an active layer 17. The first laminate 15 serves as a first distributed Bragg reflector, and specifically, includes first semiconductor layers 15a and second semiconductor layers 15b, which are alternately arranged so as to form the first distributed Bragg reflector. The first intermediate layer 13 is disposed between the first laminate 15 and the active layer 17. The first intermediate layer 13 includes a first portion 13a and a second portion 13b. The first laminate 15, the first and second portions 13a and 13b of the first intermediate layer 13, and the active layer 17 are sequentially arranged in the direction of the first axis Ax1. In the first intermediate layer 13, the first portion 13a extends from the first laminate 15 to the second portion 13b, and the second portion 13b extends from the active layer 17 to the first portion 13a. The first portion 13a of the first intermediate layer 13 includes a first dopant, and the first laminate 15 includes the first dopant. Semiconductors are doped with the dopant to be conductive. The first laminate 15 has a concentration of the first dopant greater than that in the first portion 13a of the first intermediate layer 13, and in the first intermediate layer 13, the concentration of the first dopant in the first portion 13a is larger than that in the second portion 13b of the first intermediate layer 13. In the active layer 17, the concentration of the first dopant is less than 1×10¹⁶ cm⁻³.

In the vertical cavity surface emitting laser 11, the first intermediate layer 13 is provided with the first and second portions 13a and 13b, which are disposed between the first laminate 15 and the active layer 17. In the first intermediate layer 13, the first portion 13a is disposed to fill in between the first laminate 15 and the second portion 13b, and the second portion 13b is disposed to fill in between the active layer 17 and the first portion 13a. The second portion 13b has a dopant concentration smaller than that of the first portion 13a, and the first intermediate layer 13 allows the active layer 17, which is grown as undoped, to have a dopant concentration of less than 1×10¹⁶ cm⁻³. The first intermediate layer 13, which has the second portion 13b between the first portion 13a and the active layer 17, is provided with a structure allowing the diffusion of the dopant from the first laminate 15 during the fabrication to hardly increase the concentration of the dopant in the active layer 17. This structure can prevents dopant atoms in the first laminate 15 from reaching the active layer 17 by diffusion to keep the dopant concentration in the active layer 17 low and specifically to make the dopant concentration therein smaller than a lower detection limit. The second portion 13b with the low dopant concentration results in that the reduction in the occurrence of the generation of non-radiative recombination centers in the active layer 17. Further, the vertical cavity surface emitting laser 11 provides carriers, which flow from the first laminate 15 to the active layer 17, with the doped first portion 13a (i.e., the first portion 13a having a dopant concentration lower than that of the first laminate 15 and larger than that of the second portion 13b of the first intermediate layer 13).

The first laminate 15 includes, for example, an n-type dopant, and has an n-type dopant concentration of, for example, 1×10¹⁸ cm⁻³ or more. The n-type dopant of the first laminate 15 may be, for example, 1×10¹⁹ cm⁻³ or less. The vertical cavity surface emitting laser 11 allows the first intermediate layer 13 to separate the first laminate 15 with the an n-type dopant concentration of 1×10¹⁸ cm⁻³ or more from the active layer 17.

The fabrication of the vertical cavity surface emitting laser 11 grows semiconductor layers for the first laminate 15, and further grows a remaining semiconductor region on these semiconductor layers for the first laminate 15 to form an epi-wafer. Growing this remaining semiconductor region brings the semiconductor layers for the first laminate 15 an additional heat. The total amount of the thermal energy is associated with the thickness of not the semiconductor layers of the first laminate 15 but the remaining semiconductor region thereon. The first intermediate layer 13 is provided with the first and second portions 13a and 13b of different n-type dopant concentrations, which results in the prevention of the diffusion of dopant atoms from the first laminate 15 of 1×10¹⁸ cm⁻³ or more to the active layer 17, so that the dopant concentration of the active layer 17 can be kept very low, for example, smaller than the lower detection limit. The second portion 13b is provided with the dopant concentration thus lowered, which allows the generation of the non-radiative recombination center to hardly occur in the active layer 17 due to the diffused dopant.

The vertical cavity surface emitting laser 11 has a dopant profile (e.g., the dopant profile PD shown in FIG. 1) of the first-dopant concentration, and this dopant profile has a part monotonically varying in the first and second portions 13a and 13b of the first intermediate layer 13 in the direction from the first laminate 15, which is heavily doped with the first dopant, to the active layer 17.

The vertical cavity surface emitting laser 11 further includes a lower contact layer 21. In the present embodiment, the first laminate 15 is provided with an upper laminate portion 15u and a lower laminate portion 15d, and the lower contact layer 21 is disposed between the upper and lower laminate portions 15u and 15d. The upper and lower laminate portions 15u and 15d are arranged to form the first distributed Bragg reflector, and each include first semiconductor layers 15a and second semiconductor layers 15b, which are alternately arranged so as to form the first distributed Bragg reflector including the first laminate 15.

In the first intermediate layer 13, the first portion 13a has a concentration of the first dopant of, for example, 1×10¹⁷ cm⁻³ or more, and the second portion 13b has a concentration of the first dopant of, for example, less than 1×10¹⁷ cm⁻³. The symbol “C1” shown in FIG. 1 indicates a dopant level of, for example, 1×10¹⁷ cm⁻³. The first intermediate layer 13 of a substantially single material allows the dopant profile PD to have a part monotonically decreasing in the first intermediate layer 13. Specifically, the dopant profile PD, which represents variation in the dopant concentration, has a shape monotonically decreasing in the first portion 13a of the first intermediate layer 13 from a value at the boundary between the first laminate 15 and the first intermediate layer 13, and has a dopant concentration value of less than 1×10¹⁷ cm⁻³ at the boundary between the first and second portions 13a and 13b.

In the present embodiment, the active layer 17 is distanced from the first laminate 15 by 5 nanometers or more in the direction of the first axis Ax1, and the first intermediate layer 13 is between the first laminate 15 and the active layer 17. A distance less than the lower limit may not prevent a lot of dopant atoms from reaching the active layer by thermal diffusion during the fabrication, leading to the generation of non-radiative recombination centers in the active layer. A small value in this distance cannot bring the laser a sufficient light confinement into the active layer, thereby lowering the emission intensity of the laser. The active layer 17 is distanced from the first laminate 15 by not more than 40 nanometers in the direction of the first axis Ax1. Distances of more than this upper limit provide an electrical carrier path between the lower contact layer and the active layer with a low electrical conductance (the resistance is made high), making it difficult to obtain high-speed modulation in the laser. Distances of the upper limit or lower ensure an excellent conductance.

The vertical cavity surface emitting laser 11 provides an electrical path from the first laminate 15 to the second portion 13b with the first portion 13a (the first portion 13a with a dopant concentration higher than 1×10¹⁶ cm⁻³), so that carriers can flow from the first laminate 15 to the active layer 17 through the first portion 13a. The vertical cavity surface emitting laser 11 with the thick laminates for the two distributed Bragg reflectors allows the intermediate layer 13 of the first and second portions 13a and 13b to prevent a dopant distribution between the lower contact layer 21 and the active layer 17, specifically in the vicinity of the active layer 17, from degrading high-speed modulation performances.

In the vertical cavity surface emitting laser 11, at least one of the first portion 13a, which has a first-dopant concentration of 1×10¹⁷ cm⁻³ or more, and the second portion 13b, which has a first-dopant concentration of less than 1×10¹⁷ cm⁻³, has a dopant profile which has a part monotonically changing in the direction from the first laminate 15 to the active layer 17. The first dopant encompasses, for example, silicon (Si), sulfur (S) and tellurium (Te). Alternatively, the first dopant can encompass, for example, zinc (Zn), beryllium (Be), magnesium (Mg), and carbon (C).

In the vertical cavity surface emitting laser 11, the active layer 17 can include a light emitting layer of a bulk structure. Alternatively, the active layer 17 may have a quantum well structure MQW. The quantum well structure MQW can include, for example, Al_{X}Ga_{1-X}As/In_{1-Y}Ga_{Y}As and/or In_{U}Al_{V}Ga_{1-U-V}As/Al_{X}Ga_{1-X}As. The vertical cavity surface emitting laser 11 can be provided with a reduced density of non-radiative recombination centers, which may be generated by diffused dopant atoms, in the quantum well structure MQW.

Specifically, the following relation is satisfied in the quantum well structure MQW containing Al_{X}Ga_{1-X}As/In_{1-Y}Ga_{Y}As, where X is 0.1 or more and 0.5 or less, and Y is 0.05 or more and 0.5 or less (0.1≤X≤0.5; and 0.05≤Y≤0.5). The aluminum composition of not more than the upper limit of X can avoid oxidation of aluminum therein. Specifically, the mesa has a side face, exposed to the air before being covered with a protective film in the fabrication process, containing aluminum (Al), and this exposure to the air leads to unintentional oxidization of aluminum therein. The oxidization provides the MQW with stress to prevent the laser from lasing at a desired oscillation wavelength. The aluminum composition of not less than the lower limit of X can provide the active layer with a refractive index which allows the MQW to confine light therein, thereby enabling a larger optical emission. The composition of Y in the above range allows the MQW to emit light of a desired oscillation wavelength. Alternatively, the following relation is satisfied in the quantum well structure MQW containing In_{U}Al_{V}Ga_{1-U-V}As/Al_{X}Ga_{1-X}As, where U is 0.05 or more and 0.5 or less; and V is more than zero and 0.2 or less; and X is 0.1 or more and 0.5 or less (0.05≤U≤0.5; 0≤V≤0.2; and 0.1≤X≤0.5.). The ranges (U and V) of aluminum (Al) and indium (In) of the well layers allow the MQW to emit light of a desired oscillation wavelength, and the range (X) of aluminum (Al) of the barrier layers can avoid the undesired oxidation of aluminum as above. The quantum well structures of these compositions can also reduce the generation of non-radiative recombination centers produced by the dopant diffusion.

The vertical cavity surface emitting laser 11 further includes a second intermediate layer 23 and a second laminate 25. The second laminate 25 is provided for a second distributed Bragg reflector. Specifically, the second laminate 25 includes first semiconductor layers 25a and second semiconductor layers 25b, which are alternately arranged to form the second distributed Bragg reflector. The second intermediate layer 23 is disposed between the active layer 17 and the second laminate 25. The second laminate 25, the second intermediate layer 23, and the active layer 17 are sequentially arranged in the direction of the first axis Ax1. The active layer 17 is disposed between the first intermediate layer 13 and the second intermediate layer 23. The second laminate 25 includes a second dopant of a conductivity type opposite to that of the first dopant. Dopants can impart conductivity types to semiconductors. The second intermediate layer 23 can be doped with the second dopant.

The second laminate 25 may include, for example, a p-type dopant, and has a concentration of the p-type dopant of, for example, 1×10¹⁸ cm⁻³ or more. The p-type dopant concentration of the second laminate 25 can be, for example, 1×10¹⁹ cm⁻³ or less. In the vertical cavity surface emitting laser 11, the second intermediate layer 23 separates the second laminate 25, which has a high p-type dopant concentration of 1×10¹⁸ cm⁻³ or more, from the active layer 17.

The vertical cavity surface emitting laser 11 may be provided with another type of a second laminate 25 containing an n-type dopant in place of the present second laminate 25, doped with the p-type dopant, and then the vertical cavity surface emitting laser 11 may have another type of a first laminate 15 containing a p-type dopant in place of the present first laminate 15, doped with the n-type dopant.

Where possible, the second intermediate layer 23 includes a first portion 23a and a second portion 23b, and the first and second portions 23a and 23b are disposed between the second laminate 25 and the active layer 17. Specifically, the second laminate 25, the first and second portions 23a and 23b of the second intermediate layer 23, and the active layer 17 are sequentially arranged in the direction of the first axis Ax1. In the second intermediate layer 23, the first portion 23a extends from the second laminate 25 to the second portion 23b, and the second portion 23b extends from the active layer 17 to the first portion 23a. The second portion 23b has a dopant concentration smaller than that of the first portion 23a, and the active layer 17 may be provided with the concentration of the second dopant of less than 1×10¹⁶ cm⁻³. The second dopant is distributed in the second intermediate layer 23 and the second laminate 25 to form a dopant profile similar to the profile of the first dopant in the first intermediate layer 13 and the first laminate 15. The second dopant encompasses, for example, zinc (Zn), beryllium (Be), magnesium (Mg), and carbon (C). Alternatively, the second dopant encompasses, for example, silicon (Si), sulfur (S) and tellurium (Te).

In the second intermediate layer 23, the first portion 23a has a concentration of the second dopant of, for example, 1×10¹⁷ cm⁻³ or more, and the second portion 23b has a concentration of the second dopant of, for example, less than 1×10¹⁷ cm⁻³. More specifically, the dopant profile has a shape increasing in the first portion 23a of the second intermediate layer 23 from the value at the boundary between the first laminate 15 and the second intermediate layer 23 to a dopant concentration of less than 1×10¹⁷ cm⁻³ in the second portion 23b. The second intermediate layer 23 of a substantially single material has a dopant profile decreasing in the second intermediate layer 23, which is similar to the dopant profile PD.

The first portion 23a (having a dopant concentration of greater than 1×10¹⁶ cm⁻³) is disposed on a path, given to carriers flowing from the second laminate 25 to the active layer 17, from the second laminate 25 to the second portion 23b of the second intermediate layer 23. In the vertical cavity surface emitting laser 11 that includes the thick laminates (15 and 25) forming the two distributed Bragg reflectors, the second intermediate layer 23, which has the first and second portions 23a and 23b between the active layer 17 and the upper contact layer 29, can prevent the dopant distribution in the vicinity of the active layer 17 from degrading high-speed modulation performances thereof.

In the present embodiment, the second laminate 25 is distanced from the active layer 17 by not less than 5 nanometers in the direction of the first axis Ax1, and the second intermediate layer 23 fills in between the second laminate 25 and the active layer 17. The distance of 5 nanometers or more enhances the confinement of light generated in the active layer into the active layer and the vicinity thereof. The second laminate 25 is distanced from the active layer 17 by not more than 40 nanometers in the direction of the first axis Ax1. This distance of 40 nanometers or more ensures a sufficient conductivity on the path between the upper contact layer and the active layer to enable high-speed modulation.

The vertical cavity surface emitting laser 11 further includes an upper contact layer 29. In the present embodiment, the second laminate 25 mounts the upper contact layer 29. The vertical cavity surface emitting laser 11 further includes a current confinement structure 31. In the present embodiment, the second laminate 25 is provided with the current confinement structure 31. Specifically, the current confinement structure 31 includes a current aperture region 31a and a current blocking region 31b. The current blocking region 31b encircles the current aperture region 31a, and the current blocking region 31b can guide carriers to allow the carriers to flow from the upper contact layer 29 through the current aperture region 31a. The current aperture region 31a includes a III-V compound semiconductor, and the current blocking region 31b includes oxide of a constituent element(s) of the III-V compound semiconductor.

In the embodiment, the active layer 17 is provided with the quantum well structure MQW, which includes multiple well layers 17a and one or more barrier layers 17b. The well layers 17a and the barrier layers 17b are alternately arranged in the direction of the first axis Ax1. In the present embodiment, the second portion 13b of the first intermediate layer 13 is disposed between the first portion 13a and one of the outermost well layers 17a of the active layer 17. The second portion 23b of the second intermediate layer 23 is disposed between the first portion 23a and the other of the outermost well layers 17a of the active layer 17.

The active layer 17 is disposed between the first and second laminates 15 and 25, and the arrangement of the active layer 17, the first laminate 15 and the second laminate 25 provides the vertical cavity surface emitting laser 11 with the optical cavity thereof.

The vertical cavity surface emitting laser 11 may further include a substrate 27. The first intermediate layer 13 and the first laminate 15 are arranged between the substrate 27 and the active layer 17. The substrate 27 includes, for example, GaAs, GaP, GaSb, InP, InAs, AlSb, or AlAs. The substrate 27 has a first region 27a and a second region 27b. The second region 27b encircles the first region 27a, and the substrate 27, specifically the first and second regions 27a and 27b, mounts the lower laminate portion 15d of the first laminate 15 and the lower portion of the lower contact layer 21.

The vertical cavity surface emitting laser 11 has a post structure 33. The post structure 33 is disposed on the first region 27a of the substrate 27. The post structure 33 has an upper face 33a and a side face 33b. In the present embodiment, the post structure 33 is provided with the upper contact layer 29, the second laminate 25, the second intermediate layer 23, the active layer 17, the first intermediate layer 13, the upper laminate portion 15u of the first laminate 15, and an upper portion of the contact layer 21.

The vertical cavity surface emitting laser 11 includes an insulating protective film 35, an upper electrode 37, and a lower electrode 39. The insulating protective film 35 covers the top and side faces 33a and 33b of the post structure 33 and the top face of the lower portion of the lower contact layer 21. The upper and lower electrodes 37 and 39 are connected to the upper and lower contact layers 29 and 21, respectively. The insulating protective film 35 has a first opening 35a on the upper face 33a of the post structure 33, and a second opening 35b on the second region 27b of the substrate 27.

The upper and lower electrodes 37 and 39 make contact with the upper and lower contact layers 29 and 21 through the first and second openings 35a and 35b, respectively.

An exemplary structure for the vertical cavity surface emitting laser 11

Substrate 27: GaAs substrate.
Lower contact layer 21: n-type Al_{X}Ga_{1-X}As, having a thickness of 100 to 800 nm with a dopant concentration of 2×10¹⁸ cm⁻³.
First laminate 15.
Upper laminate portion 15u: n-type Al_{X}Ga_{1-X}As/n-type Al_{Y}Ga_{1-Y}As having a stacking number of 5 to 30 cycles; a dopant (Si) concentration of 2×10¹⁸ cm⁻³; and a thickness of 400 to 5400 nm, where n-type Al_{X}Ga_{1-X}As having a thickness of 40 to 90 nm, and n-type Al_{Y}Ga_{1-Y}As having a thickness of 40 to 90 nm.
Lower laminate portion 15d: i-type Al_{X}Ga_{1-X}As/i-type Al_{Y}Ga_{1-Y}As having a stacking number of 20 to 40 cycles, and a thickness of 1600 to 5200 nm, where i-type Al_{X}Ga_{1-X}As having a thickness of 40 to 90 nm; and a thickness of i-type Al_{Y}Ga_{1-Y}As 40 to 90 nm.
First intermediate layer 13: Al_{Z}Ga_{1-Z}As with a thickness of 5 to 20 nm, for example 10 nm.
Active layer 17: GaAs/AlGaAs quantum well structure,
InGaAs/AlGaAs quantum well structure, or AlInGaAs/AlGaAs quantum well structure, with a thickness of 10 to 80 nm.
Second intermediate layer 23: p-type Al_{Z}Ga_{1-Z}As with a thickness of 5 to 20 nm, for example 10 nm.
Second laminate 25: p-type AlₓGa₁₋ₓAs/p-type Al_{y}Ga_{1-y}As, having a dopant concentration of 5×10¹⁸ cm⁻³, a stacking number of 5 to 30 layers, and a thickness of 400 to 5400 nm, where p-type AlₓGa₁₋ₓAs having a thickness of 40 to 90 nm, and p-type Al_{Y}Ga_{1-Y}As having a thickness of 40 to 90 nm.
Current confinement structure 31.
Current aperture region 31a: AlGaAs (having an Al composition of 0.9 to 0.96) with a thickness of 10 to 50 nm.
Current blocking region 31b: Group III oxide, specifically aluminum oxide and/or gallium oxide.
Upper contact layer 29: p-type GaAs or p-type AlGaAs having a dopant concentration of 1×10¹⁹ cm⁻³, and a thickness of 100 to 350 nm.
Insulating protective film 35: silicon-based inorganic insulating film, such as silicon oxide and silicon oxynitride.
Upper electrode 37: AuGeNi.
Lower electrode 39: AuGeNi.

Referring to FIG. 1, symbol “C1” indicates a dopant level of, for example, 1×10¹⁷ cm⁻³. In the first intermediate layer 13 of a substantially single material, the dopant profile PD, which represents variation of the dopant concentration in the first intermediate layer 13, has a part decreasing in the first intermediate layer 13. Specifically, the dopant profile PD has a part decreasing in the first portion 13a from a value at the boundary between the first laminate 15 and the first intermediate layer 13, and may have a dopant concentration of less than 1×10¹⁷ cm⁻³ in the second portion 13b.

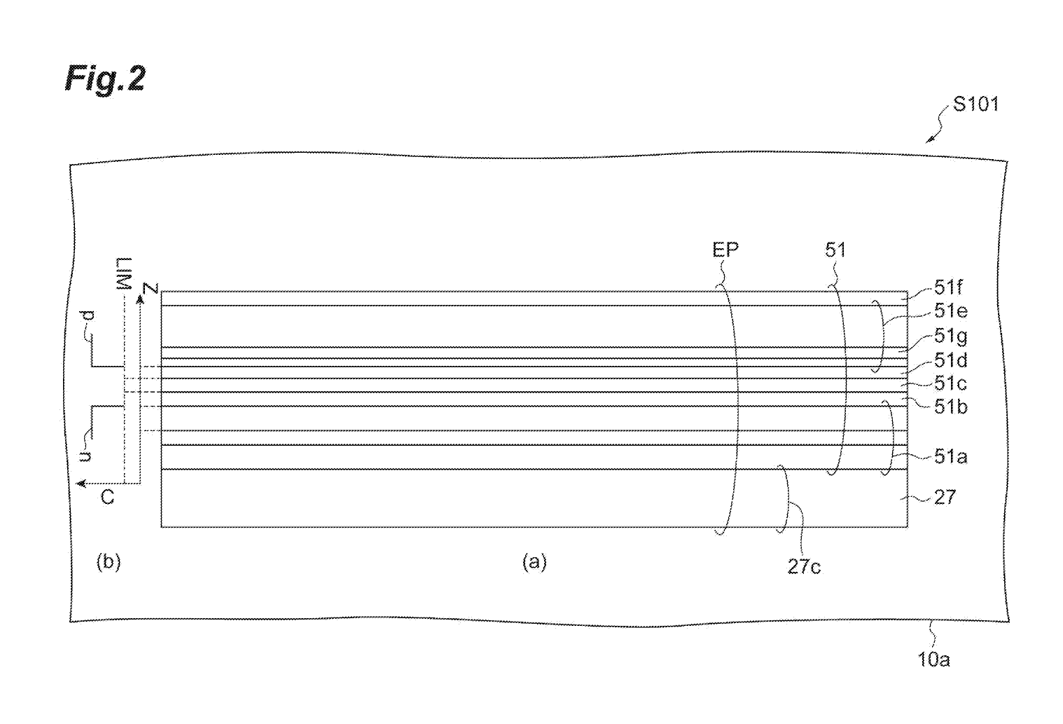

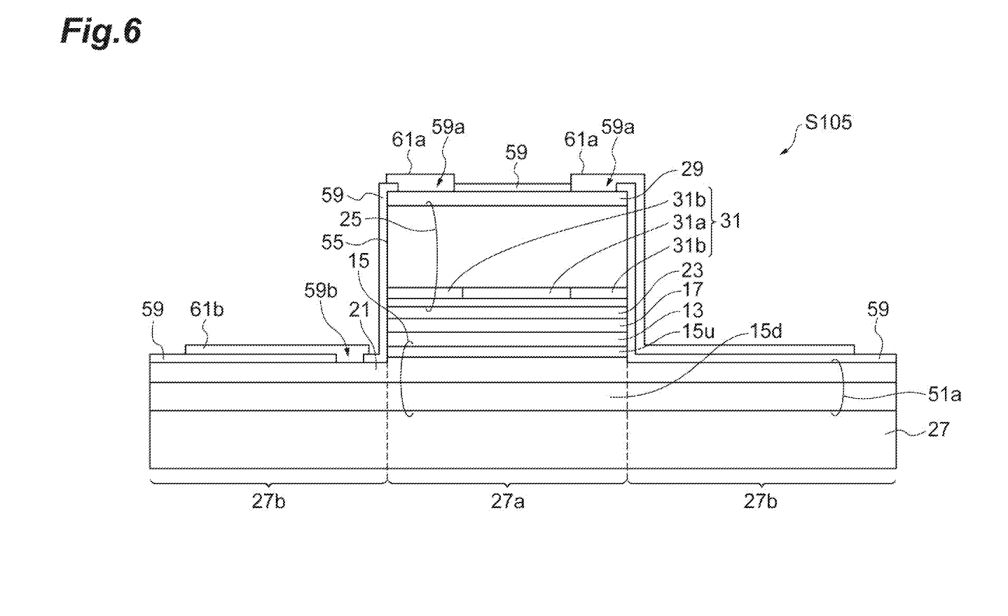

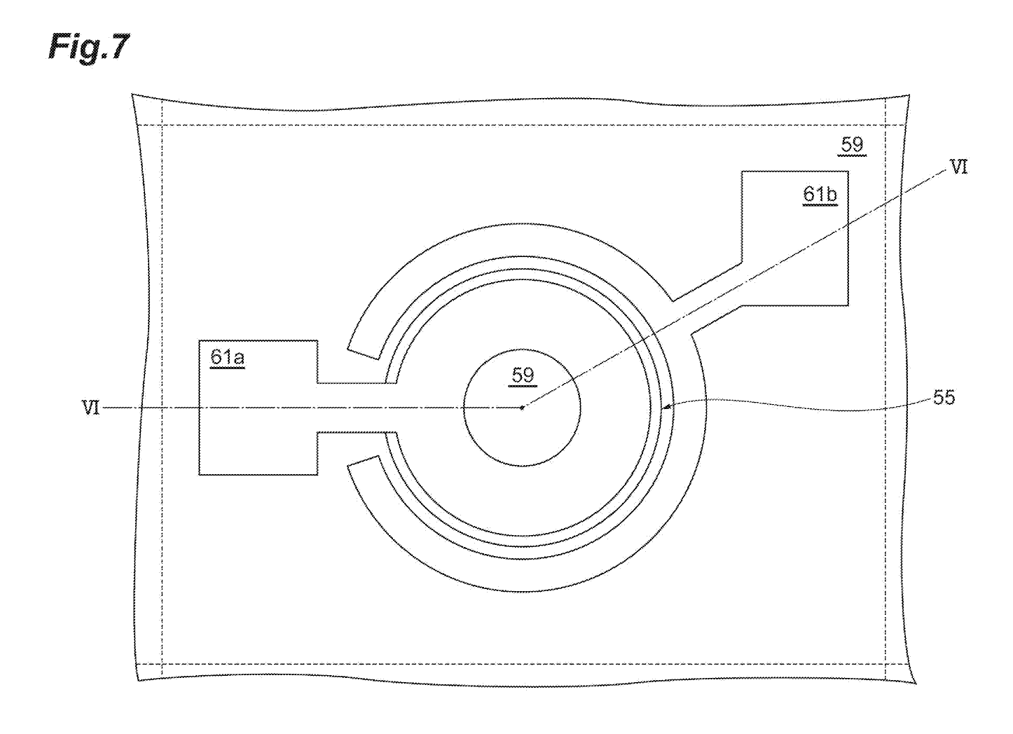

FIGS. 2 to 7 are schematic view each showing a major step in a method for fabricating the vertical cavity surface emitting laser according to the present embodiment. FIGS. 2 to 6 each show a single device section. FIG. 6 shows a cross section taken along line VI-VI shown in FIG. 7. FIGS. 2 to 5 each show a schematic cross-section taken along a line associated with the line shown in FIG. 7. With reference to FIGS. 2 to 7, a description will be given of the method for fabricating the vertical cavity surface emitting laser according to the present embodiment below. For easy understanding, the reference numerals shown in FIG. 1 will be used in the following description, where possible.

The substrate 27 is prepared for crystal growth. The substrate 27 thus prepared is loaded to a growth reactor 10a. As shown in part (a) of FIG. 2, in step S101, a semiconductor stack 51 is formed on the substrate 27. Specifically, the semiconductor stack 51 is grown on the principal surface 27c of the substrate 27. This growth is carried out by, for example, metal organic vapor phase epitaxy and/or molecular beam epitaxy. The semiconductor stack 51 includes a first semiconductor stack 51a for the first distributed Bragg reflector, a first semiconductor layer 51b for the first intermediate layer, a third semiconductor stack 51c for the active layer, a second semiconductor layer 51d for second intermediate layer, a second laminate 51e for the second distributed Bragg reflector, and a third semiconductor layer 51f for the contact layer. The crystal growth sequentially forms the first laminate 51a, the first semiconductor layer 51b, the third semiconductor laminate 51c, the second semiconductor layer 51d, the second laminate 51e, and the third semiconductor layer 51f. The first semiconductor layer 51b for the first intermediate layer, the third semiconductor stack 51c for the active layer, and the second semiconductor layer 51d for the second intermediate layer are grown at a temperature of 600 degrees Celsius, and the first semiconductor stack 51a for the first distributed Bragg reflector, the second semiconductor stack 51e for the second distributed Bragg reflector, and the third semiconductor layer 51f for the contact layer are grown at a temperature of 700 degrees Celsius. Specifically, the first semiconductor stack 51a includes semiconductor layers for the lower stack portion 15d of the first laminate 15, the lower contact layer 21, and the upper stack portion 15u of the first laminate 15. The second semiconductor stack 51e includes semiconductor layers 51g for the second laminate 25 and the current confinement structure. The semiconductor layers for the lower contact layer 21 and the upper laminate portion 15u of the first laminate 15 are grown while supplying, for example, n-type dopant material, whereas the semiconductor layers for the second laminate 25 and the third semiconductor layer 51f are grown while, for example, p-type dopant material. The lower laminate portion 15d of the first laminate 15, the first semiconductor layer 51b for the first intermediate layer, the third semiconductor stack 51c for the active layer, and the second semiconductor layer 51d for the second intermediate layer are grown with supplying neither n-type nor p-type dopant material to form an undoped semiconductor. These growing processes produce an epitaxial substrate EP. The epitaxial substrate EP has p-type and n-type dopant profiles as shown in part (b) of FIG. 2. The symbol “LIM” indicates the detection limit of the dopant. The third semiconductor stack 51c for the active layer is made undoped, and the first semiconductor layer 51b and the second semiconductor layer 51d for the intermediate layers are made substantially undoped.

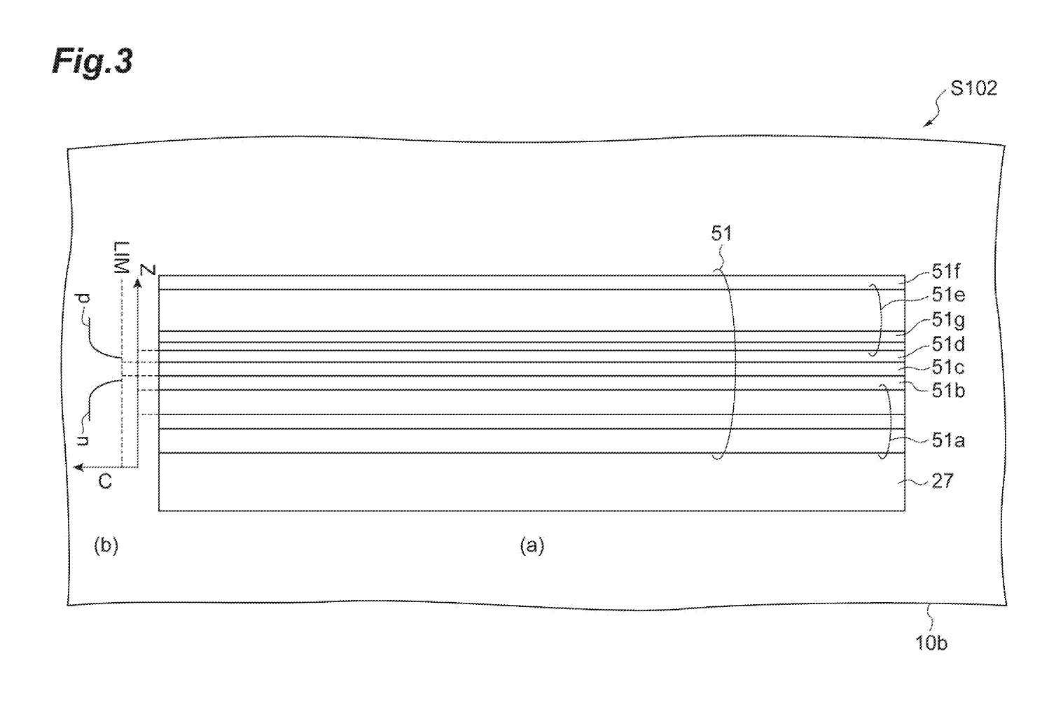

The epitaxial substrate EP is loaded to, for example, a heat treatment apparatus 10b. As shown in part (a) of FIG. 3, in step S102, an additional heat treatment is applied to the semiconductor stack 51 and the substrate 27. This heat treatment can be carried out in the growth reactor 10a just after the crystal growth without using the heat treatment apparatus 10b. The heat treatment apparatus 10b forms an atmosphere for heat treatment, for example, a hydrogen atmosphere, and this atmosphere is used for heat treatment of the epitaxial substrate EP. The heat treatment temperature can be 700 degrees Celsius or higher, and the period of the heat treatment can be one hour or more. In the embodiment, the growth reactor 10a is used for the heat treatment. Specifically, the third semiconductor layer 51f is grown at a temperature of 700 degrees Celsius while supplying p-type dopant and raw material for the uppermost semiconductor layer, for example, the upper contact layer to the growth reactor 10a. The raw material gas and the p-type dopant gas are stopped to end semiconductor growth, and the supply of arsine to the growth reactor 10a for the heat treatment follows the termination of the growth. The heat treatment temperature of the growth reactor 10a is, for example 700 degrees Celsius. The heat treatment temperature is equal to or higher than the growth temperature for the semiconductor layers that exclude the third semiconductor stack 51c for the active layer and the first and second intermediate layers. The epitaxial substrate EP is placed in an atmosphere at the temperature of 700 degrees Celsius or higher for one hour or more to modify the epitaxial substrate EP, thereby obtaining a modified epitaxial substrate EP. The heat treatment can use a temperature in the range of 600 to 800 degrees Celsius, and a processing time in the range of 15 to 105 minutes. After the reforming, the temperature of the growth reactor 10a (or the heat treatment apparatus 10b) is lowered to room temperature. The temperature drop is carried out, for example, in an atmosphere of hydrogen. After this temperature dropping process, the modified epitaxial substrate EP is loaded from the growth reactor 10a (or the heat treatment apparatus 10b). The modified epitaxial substrate EP has p-type and n-type dopant profiles as shown in part (b) of FIG. 3. The first and second semiconductor layers 51b and 51d for the intermediate layers thus modified each have respective dopant profiles reformed by thermal diffusion. The third semiconductor stack 51c for the active layer is, however, kept undoped. These processes provide the epitaxial substrate with the first and second portions 13a and 13b of the first intermediate layer 13. A shorter processing time, for example, 15 minutes is better at the processing temperature of 800 degrees Celsius. A processing period of time more than 30 minutes or longer at the processing temperature of 800 degrees Celsius may cause excessive diffusion of the dopant in the second portion 13b. The heat treatment at a temperature of 600 degrees Celsius needs a long processing time ranging from, for example, 90 to 105 minutes. The first semiconductor layer of a large thickness needs a long processing time. A processing period of time shorter than 75 minutes at the processing temperature of 600 degrees may cause insufficient diffusion of the dopant in view of forming the first portion 13a.

The method of fabricating the vertical cavity surface emitting laser 11 grows semiconductor layers for the vertical cavity surface emitting laser 11 and then applies the heat treatment, which is different from the heating for the growth, to these semiconductor layers to cause the desired diffusion of dopant atoms. Specifically, the semiconductor layers are grown on the substrate by supplying gas containing source materials to the growth reactor 10a. After this growth, the substrate is heat-treated without growing the semiconductor. This heat treatment, independently of the heating resulting from the growth, can diffuse the dopant atoms as grown, so that the first semiconductor layer 51b for the first intermediate layer 13, which is grown as undoped, can be doped with dopant atoms diffusing from the semiconductor layers for the upper laminate portion 15u of the first laminate 15. The thermal treatment makes it possible to provide the first semiconductor layer 51b, grown for the first intermediate layer 13, with a dopant profile monotonically varying in the direction from the first distributed Bragg reflector to the active layer 17.

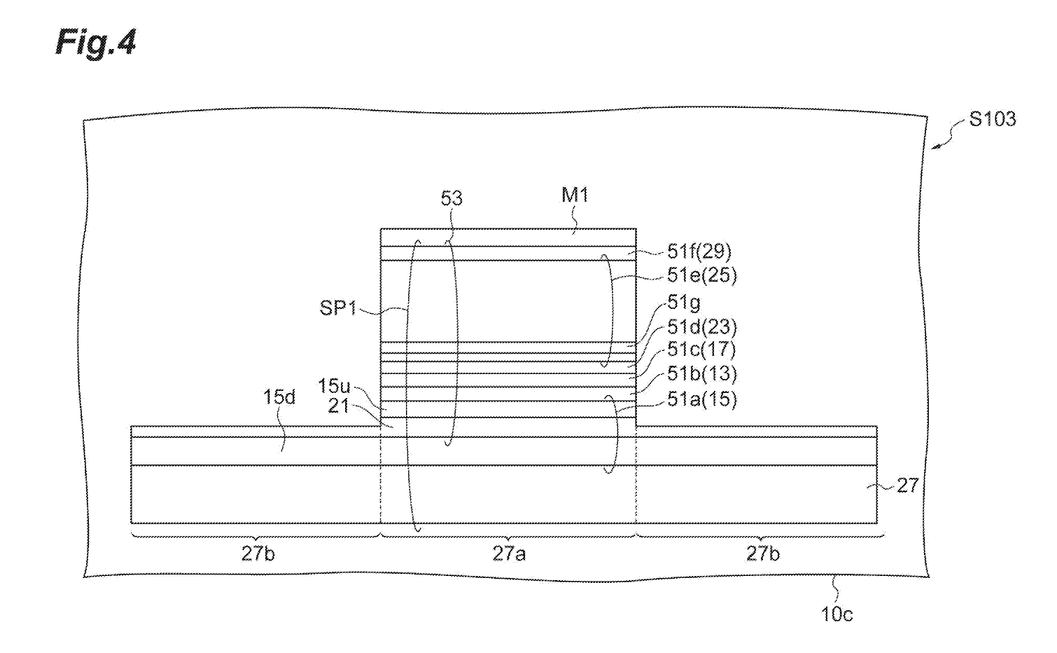

The modified epitaxial substrate EP is processed to form a substrate product having semiconductor posts. Specifically, as shown in FIG. 4, a mask M1 is formed on the modified epitaxial substrate EP in step S103. The mask M1 is fabricated, for example, by applying photolithography and etching to a silicon-based inorganic insulating film formed on the modified epitaxial substrate EP. The mask M1 has a pattern that defines the posts for the vertical cavity surface emitting laser 11. The modified epitaxial substrate EP with the mask M1 formed thereon is loaded to an etching apparatus 10c. The semiconductor stack 51 is processed by etching with the mask M1 to form a first substrate product SP1 having an exemplary semiconductor post 53 in the drawing. The semiconductor post 53 of the first substrate product SP1 has a lower end in the semiconductor layer for the lower contact layer 21. The first semiconductor stack 51a for the upper stack portion 15u of the first laminate 15 is etched such that the lower stack portion 15d of the first semiconductor stack 15a is left for the first laminate 15, thereby forming the semiconductor post 53. The semiconductor post 53 is disposed on the first region 27a of the substrate 27, and both the lower portion of the lower contact layer 21 and the first semiconductor stack 51a for the lower stack portion 15d of the first laminate 15 are disposed on the second portion 27b of the substrate 27. This etching is performed by dry etching or an aqueous solution containing, for example, phosphoric acid and hydrogen peroxide water. After the etching, the mask M1 is removed. The semiconductor post 53 has a part of the etched first semiconductor stack 51a including an etched first semiconductor layer 51b, an etched third semiconductor stack 51c, an etched second semiconductor layer 51d, an etched second laminate 51e, and an etched third semiconductor layer 51f. The semiconductor post 53 has a laminate structure in the central portion thereof that is the substantially the same as that of the post structure 33 of the vertical cavity surface emitting laser 11 except for the semiconductor layer 51g for the current confinement structure. For easy understanding, reference numerals denoted in FIG. 1 are used in the following description, where possible. More specifically, the semiconductor post 53 is provided with the upper portion of the lower contact layer 21, the upper laminate portion 15u of the first laminate body 15, the first intermediate layer 13, the active layer 17, the second intermediate layer 23, the second laminate body 25, and the upper contact layer 29. The second laminate 25 includes the semiconductor layer 51g for the current confinement structure.

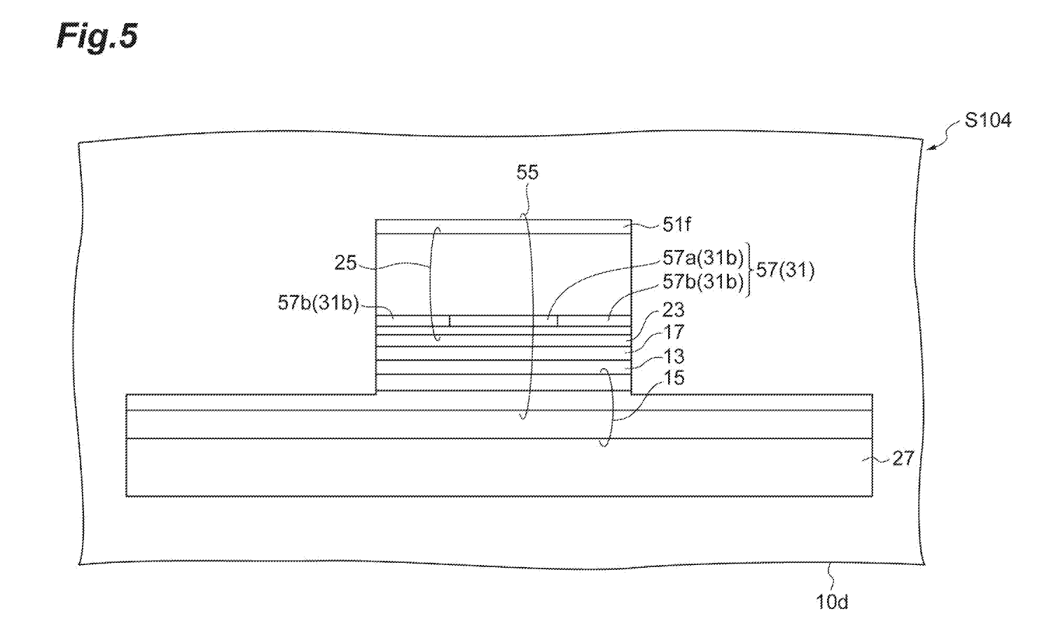

The mask M1 is removed from the first substrate product SP1, and then the first substrate product SP1 is processed to form a current confinement structure in the semiconductor post 53 thereof. Specifically, in step S104, as shown in FIG. 5, the first substrate product SP1 is loaded to an oxidation reactor 10d, which is provided with an oxidizing atmosphere. The semiconductor post 53 is exposed to the oxidizing atmosphere to form a second substrate product SP2 that includes a post 55 having a current confinement structure 57 (31). In the present embodiment, the oxidizing atmosphere contains a high-temperature steam (the temperature of which is, for example, 400 degrees Celsius). The high-temperature steam oxidizes a semiconductor layer containing Al as a constituent element at the side face of the semiconductor post 53 depending upon its Al composition. The oxidizing progress from the side face of the semiconductor post 53, and in particular, the semiconductor layer 51g having the highest Al composition, specifically, AlGaAs (Al composition 0 9 to 0.96, a thickness of 10 to 50 nm) is most easily oxidized among semiconductor layers in the post. The current confinement structure 57 (31) thus formed has a current aperture 57a (31a) in the inner portion of the post 55, and a current blocking region 57b (31b) in the outer portion of the post 55. The current blocking region 57b circumferentially extends along the side face of the post 55 to encircle the current aperture 57a (31a). The current aperture 57a (31a) is made of the semiconductor as grown, specifically AlGaAs (Al composition 0.9 to 0.96), and the current blocking region 57b is made of oxides, specifically aluminum and gallium oxides, which are produced from the semiconductor by oxidation. The oxidation process brings the current confinement structure 57 (31) in the second substrate product SP2 to completion, and the second substrate product SP2 is unloaded out of the oxidizing reactor 10d.

The post 55 thus formed is provided with the upper portion of the lower contact layer 21, the upper laminate portion 15u of the first laminate 15, the first intermediate layer 13, the active layer 17, the second intermediate layer 23, the second laminate 25, and the upper contact layer 29. The second laminate 25 is provided with the current confinement structure 31 (57). This heating keeps the dopant-concentration profile in the first portion 13a and the second portion 13b of the first intermediate layer 13 substantially unchanged.

After forming the current confinement structure 31, a passivation film and electrodes are formed on the second substrate product SP2. As shown in FIGS. 6 and 7, in step S105, an insulating film for the passivation film 59 is formed by vapor deposition on the upper and side faces of the post 55, which located on the first region 27a of the substrate 27, and the first semiconductor stack 51a and the lower portion of the contact layer 21, which is located on the second region 27b of the substrate 27. The passivation film 59 may include, for example, SiN. The passivation film 59 has a first opening 59a on the upper face of the post 55, which is located on the first region 27a, and a second opening 59b on the upper face of the lower portion of the lower contact layer 21 and the first semiconductor stack, which are located on the second region 27b. The first and second electrodes 61a and 61b are formed on the passivation film 59 by photolithography and vapor deposition. The first and second electrodes 61a and 61b make contact with the upper and lower contact layers 29 and 21 through the first and second openings 59a and 59b of the passivation film 59, respectively.

The product that is produced by the above steps shown in FIGS. 2 to 7 is divided with a dicer to form semiconductor chips each of which includes the vertical cavity surface emitting laser 11.

The above method brings the vertical cavity surface emitting laser 11 to completion, and the vertical cavity surface emitting laser 11 is provided with the first and second portions 13a and 13b of the first intermediate layer 13, which is between the active layer 17 and the first laminate 15. In the first intermediate layer 13, the first portion 13a is between the second portion 13b and the first laminate 15, and the second portion 13b is between the first portion 13a and the active layer 17. The first portion 13a is provided with the concentration of the first dopant, which is greater than or equal to 1×10¹⁷ cm⁻³ and the second portion 13b is provided with, if any, the concentration of the first dopant less than 1×10¹⁷ cm⁻³. The first intermediate layer 13 is provided with the second portion 13b between the active layer 17 and the first portion 13a, thereby preventing the dopant atoms in the first laminate 15 from diffusing to the active layer 17 during the fabrication, so that the dopant in the active layer 17 can be made very low, for example smaller than the detection limit. The second portion 13b with a lower dopant concentration of the diffused dopant atoms can be less likely to generate non-radiative recombination centers in the active layer 17. The electrical path, which is provided with the first portion 13a (the first portion 13a having a higher dopant concentration than that of the second portion 13b), on the first laminate 15 to the second portion 13b of the first intermediate layer 13 can be given to the carriers that flow from the first laminate 15 to the active layer 17.

### EXAMPLE

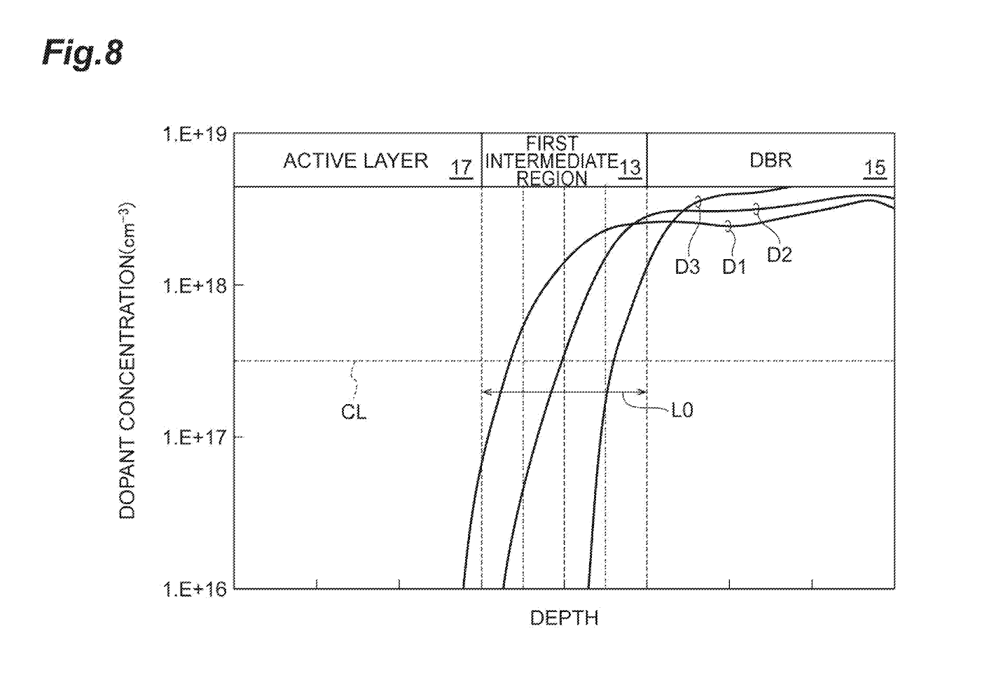

FIG. 8 shows dopant profiles of surface emitting lasers for optical communication over the first laminate 15, the first intermediate layer 13 and the active layer 17. The horizontal axis indicates coordinates on the first axis Ax1, and the vertical axis indicates the n-type (silicon) dopant concentration. In FIG. 8, for example, “1.0E+18” represents 1×10¹⁸. Vertical cavity surface emitting lasers, referred to as Devices D1, D2, and D3, in this example are fabricated by applying different heat treatments to epitaxial substrates of the same epitaxial structure. In each of Devices D1, D2, and D3, the first intermediate layer 13 has a thickness of 40 nm, and the first laminate 15 has an n-type dopant concentration of 1×10¹⁸ cm⁻³ or more. Devices D1, D2, and D3 have respective n-type dopant profiles shown in FIG. 8. The electrical characteristics of the devices D1, D2, and D3 are measured.

Device D1 exhibits a threshold current of 1.4 milliamperes, and the devices D2 and D3 each exhibit a threshold current of 1.0 milliamperes. The active layers of Devices D2 and D3 each have an n-type dopant concentration of 1×10¹⁶ cm⁻³ or less. The active layer of the device D1, however, has an n-type dopant concentration of 1×10¹⁶ cm⁻³ or more, and this results in that the active layer with a large amount of n-type dopant atoms increases the density of non-radiative recombination centers.

Device D3 exhibits a maximal modulation frequency of 16 gigahertz, and Devices D1 and D2 each exhibit a maximal modulation frequency of 18 gigahertz. In each of the devices D2 and D3, the first intermediate layer 13, which is between the active layer 17 and the first laminate 15, has an n-type dopant concentration of greater than 1×10¹⁶ cm⁻³ at the center thereof in the direction of the first axis Ax1. In Device D3, the first intermediate layer 13 has an n-type dopant concentration of 1×10¹⁶ cm⁻³ or less at the center thereof, resulting in that the electric resistance in the first intermediate layer 13 may restrict the maximal modulation frequency.

As shown in FIG. 8, the dopant profiles of the devices D1, D2, and D3 monotonously decrease in the direction from the first laminate 15 to the active layer 17. The dopant profiles of the devices D1, D2, and D3 all intersect the dashed line that indicates the doping level CL. The inventors' experiments in the present embodiment and other experiments reveal that the ratio L1/L0 is not less than 0.25 (0.25≤L1/L0) and that the ratio L1/L0 is not more than 0.75 (L1/L0≤0.75). Here, “L0” indicates the thickness of the first intermediate layer 13, and the first and second portions 13a and 13b have the thicknesses (“L1”) and (“L2”) as shown in FIG. 1, respectively. Using these representations, the L0 is represented as the sum of the thicknesses “L1” (the thickness of the first portion 13a) and “L2” (the thickness of the second portion 13b), i.e., L1+L2. The level CL indicates a dopant concentration of, for example, 5×10¹⁷ cm⁻³.

In the present embodiment, the distance between the first laminate 15 and the active layer 17 is 5 nanometers or more in the direction of the first axis Ax1, and the first intermediate layer 13 fills in between the first laminate 15 and the active layer 17. A too small distance cannot prevent the dopant atoms from reaching the active layer during the fabrication, so that the dopant diffusion increases the density of non-radiative recombination centers in the active layer, and cannot make the confinement of light generated in the active layer sufficiently strong, thereby lowering the emission intensity of the laser. The distance between the first laminate 15 and the active layer 17 is not more than 40 nanometers in the direction of the first axis Ax1, and the first intermediate layer 13 fills in between the first laminate 15 and the active layer 17. A too large distance lowers the conductance in the path ranging from the lower contact layer to the active layer (the resistance is made high), making it difficult to obtain high-speed modulation. The upper limit of the distance ensures sufficient conductance.

The inventors' experiments reveal that the first intermediate layer 13 doped with p-type dopant (zinc (Zn), beryllium (Be), magnesium (Mg), and carbon (C)) has the same advantageous effects as those in the above intermediate region.

The present embodiments can provide a vertical cavity surface emitting laser that can reduce the threshold current and enables a high-frequency modulation, and can provide a method of fabricating the same.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. A vertical cavity surface emitting laser comprising:
an active layer;
a first laminate for a first distributed Bragg reflector; and
a first intermediate layer disposed between the active layer and the first laminate,
the first intermediate layer having a first portion and a second portion,
the first laminate, the first portion and the second portion of the first intermediate layer, and the active layer being arranged along a direction of a first axis,
the first laminate and the first portion of the first intermediate layer each including a first dopant,
the active layer having a concentration of the first dopant of less than 1×10¹⁶ cm⁻³,
the first portion of the first intermediate layer extending from the first laminate to the second portion of the first intermediate layer,
the second portion of the first intermediate layer extending from the first portion of the first intermediate layer to the active layer,
the first portion of the first intermediate layer having a concentration of the first dopant smaller than that of the first laminate, and
the second portion of the first intermediate layer having a concentration smaller than that of the first portion of the first intermediate layer.

2. The vertical cavity surface emitting laser according to claim 1,
wherein
the first laminate includes a lower contact layer,
the first dopant includes at least one of silicon, sulfur, or tellurium,
the first laminate has a concentration of an n-type dopant of 1×10¹⁸ cm⁻³ or more, and
the active layer is separated from the first laminate by a distance of 5 nm or more.

3. The vertical cavity surface emitting laser according to claim 1,
wherein the first portion of the first intermediate layer has a concentration of the first dopant of 1×10¹⁷ cm⁻³ or more and the second portion of the first intermediate layer has a concentration of the first dopant of less than 1×10¹⁷ cm⁻³.

4. The vertical cavity surface emitting laser according to claim 1,
wherein the active layer has a quantum well structure of Al_{X}Ga_{1-X}As/In_{1-Y}Ga_{Y}As, where X is not less than 0.1 and not more than 0.5, and Y is not less than 0.05 and not more than 0.5.

5. The vertical cavity surface emitting laser according to claim 1,
wherein the active layer has a quantum well structure of In_{U}Al_{V}Ga_{1-U-V}As/Al_{X}Ga_{1-X}As, where U is not less than 0.05 and not more than 0.5, V is more than zero and not more than 0.2, and X is not less than 0.1 and not more than 0.5.

6. The vertical cavity surface emitting laser according to claim 1, further comprising:
a substrate;
a second laminate for a second distributed Bragg reflector; and
a second intermediate layer disposed between the active layer and the second laminate,
the second intermediate layer having a first portion and a second portion,
the first intermediate layer and the first laminate being disposed between the substrate and the active layer,
the active layer being disposed between the first laminate and the second laminate, and
the second laminate, the first portion and the second portion of the second intermediate layer, and the active layer being arranged along the direction of the first axis.

7. A method for making a vertical cavity surface emitting laser comprising:
growing a semiconductor region on a substrate; and
heating the semiconductor region and the substrate at a heating temperature;
the semiconductor region including a first laminate for a first distributed Bragg reflector, a second laminate for a second distributed Bragg reflector, a first semiconductor film for a first intermediate region, and a third semiconductor laminate for an active layer,
the first laminate, the first semiconductor film, the third semiconductor laminate, and the second laminate being arranged on a principal surface of the substrate,
growing a semiconductor region on a substrate including growing the first laminate with a first dopant, and growing the first intermediate region without the first dopant.

8. The method according to claim 7, wherein the heating temperature is 700 degrees Celsius or more.

9. The method according to claim 7, wherein heating the semiconductor region and the substrate is conducted for an hour or more.
